(19) United States
(12) Patent Application Publication
(10) Pub. No.: US 2024/0316600 A1
(43) Pub. Date: Sep. 26, 2024

(54) SUBSTRATE CLEANING DEVICE AND SUBSTRATE CLEANING METHOD

(71) Applicant: EBARA CORPORATION, Tokyo (JP)

(72) Inventors: Kenji KODERA, Tokyo (JP); Masayuki NAKANISHI, Tokyo (JP)

(21) Appl. No.: 18/030,753

(22) PCT Filed: Aug. 25, 2021
(86) PCT No.: PCT/JP2021/031127

§ 371 Date: Oct. 13, 2023

(30) Foreign Application Priority Data
Oct. 12, 2020 (JP) 2020-171681

(51) Int. Cl. B08B 1/20; B08B 1/30; B08B 1/52; B08B 1/54; H01L 21/02; H01L 21/67

(52) U.S. Cl. CPC B08B 1/20; B08B 1/30; B08B 1/52; B08B 1/54; H01L 21/02057; H01L 21/67046; H01L 21/67051

(57) ABSTRACT

The present invention relates to a substrate cleaning apparatus and a substrate cleaning method for cleaning a substrate, such as a semiconductor wafer, and more particularly to a substrate cleaning apparatus and a substrate cleaning method for cleaning a periphery of a substrate. A substrate cleaning apparatus (1) includes: a substrate holder (10) configured to hold and rotate a substrate (W); a pressing structure (22) having an internal space (R) and configured to press a cleaning tape (19) against a periphery of the substrate (W); a pressing-structure moving mechanism (30) configured to regulate a position of the pressing structure (22) in a radial direction of the substrate (W); and a pressure regulator (44) configured to regulate pressure in the internal space (R). The pressing structure (22) includes: a hollow support member (24) having an opening (25); and an elastic element (27) configured to support the cleaning tape (19). The elastic element (27) is arranged to close the opening (25).

### TECHNICAL FIELD

The present invention relates to a substrate cleaning apparatus and a substrate cleaning method for cleaning a substrate, such as a semiconductor wafer, and more particularly to a substrate cleaning apparatus and a substrate cleaning method for cleaning a periphery of a substrate.

### BACKGROUND ART

From a viewpoint of improving a yield in manufacturing of semiconductor devices, management of a surface condition in a periphery of a substrate has recently drawing attention. In manufacturing processes for semiconductor devices, various materials are deposited on a silicon wafer repeatedly to form multilayer structures. As a result, unwanted films and surface roughness are formed on the periphery of the substrate. It has been more common in recent years to transfer the substrate by holding only the periphery of the substrate. Under such situations, the unwanted films remaining on the periphery may come off the periphery onto devices formed on the substrate during various processes, resulting in a lowered yield. In order to prevent this, it has been customary to polish the periphery of the substrate using a polishing apparatus so as to remove the unwanted films from the periphery of the substrate.

However, foreign matter (particles), such as polishing debris, may adhere to the periphery of the substrate during the polishing of the periphery of the substrate. The foreign matter (particles), such as polishing debris, contaminates the substrate, resulting in a decrease in yield in semiconductor manufacturing. Therefore, conventionally, the periphery of the substrate is cleaned in order to remove the foreign matter from to the periphery of the substrate. There is a method of cleaning the periphery of the substrate by rotating a cleaning tool constituted of a PVA (polyvinyl alcohol) sponge or the like about its axis and bringing the cleaning tool into sliding contact with the periphery of the substrate.

### CITATION LIST

### Patent Literature

Patent document 1: Japanese laid-open patent publication No. 2018-161721

Patent document 2: Japanese laid-open patent publication No. 2019-216207

Patent document 3: Japanese Patent No. 4125148

### SUMMARY OF INVENTION

### Technical Problem

However, in the cleaning method described above, the adhesion of particles may cause a change in color of the cleaning tool and damage to a contact portion of the cleaning tool. Moreover, the above-described cleaning method may fail to remove the foreign matter from the substrate, leaving the foreign matter on the substrate.

It is an object of the present invention to provide a substrate cleaning apparatus and a substrate cleaning method capable of improving an effect of cleaning a periphery of a substrate.

### Solution to Problem

In an embodiment, there is provided a substrate cleaning apparatus comprising: a substrate holder configured to hold and rotate a substrate; a pressing structure having an internal space and configured to press a cleaning tape against a periphery of the substrate; a pressing-structure moving mechanism configured to control a position of the pressing structure in a radial direction of the substrate; and a pressure regulator configured to regulate pressure in the internal space, wherein the pressing structure includes: a hollow support member having an opening; and an elastic element configured to support the cleaning tape, the elastic element being arranged to close the opening.

In an embodiment, the pressing-structure moving mechanism includes a ball screw mechanism coupled to the pressing structure, and a motor configured to actuate the ball screw mechanism.

In an embodiment, the motor is a servomotor.

In an embodiment, the pressure regulator is an electropneumatic regulator.

In an embodiment, the substrate cleaning apparatus further comprises a vertically-moving mechanism configured to vertically move the pressing structure.

In an embodiment, the substrate cleaning apparatus further comprises a tape cleaning mechanism configured to clean the cleaning tape, the tape cleaning mechanism including a cleaning-liquid supply nozzle configured to supply cleaning liquid to a surface of the cleaning tape.

In an embodiment, the tape cleaning mechanism further includes a cleaning brush configured to contact the surface of the cleaning tape to clean the cleaning tape.

In an embodiment, the substrate cleaning apparatus further comprises a first reel and a second reel holding both ends of the cleaning tape, respectively, the first reel and the second reel being arranged such that the cleaning tape advances in a horizontal direction

In an embodiment, there is provided a substrate cleaning method comprising: holding and rotating a substrate by a substrate holder; while advancing a cleaning tape in a certain direction, pressing the cleaning tape against a periphery of the substrate by a pressing structure having an internal space, thereby cleaning the periphery of the substrate, wherein cleaning the periphery of the substrate comprises controlling a position of the pressing structure in a radial direction of the substrate by a pressing-structure moving mechanism, and regulating pressure in the internal space of the pressing structure by a pressure regulator, the pressing structure includes: a hollow support member having an opening; and an elastic element supporting the cleaning tape, the elastic element being arranged to close the opening.

In an embodiment, the pressing-structure moving mechanism includes a ball screw mechanism coupled to the pressing structure, and a motor configured to actuate the ball screw mechanism.

In an embodiment, the motor is a servomotor.

In an embodiment, the pressure regulator is an electropneumatic regulator.

In an embodiment, cleaning the periphery of the substrate further comprises moving the pressing structure up and down while cleaning the periphery of the substrate.

In an embodiment, the substrate cleaning method further comprises supplying a cleaning liquid by a tape cleaning mechanism to the cleaning tape that has contacted the periphery of the substrate during cleaning of the periphery of the substrate to thereby clean the cleaning tape.

In an embodiment, the substrate cleaning method further comprises supplying a cleaning liquid by a tape cleaning mechanism to the cleaning tape that has contacted peripheries of a predetermined number of substrates while advancing the cleaning tape in a certain direction to thereby clean the cleaning tape.

In an embodiment, the substrate cleaning method further comprises cleaning the periphery of the substrate while advancing the cleaning tape in an opposite direction after the cleaning tape is completely wound on either a first reel or a second reel, the first reel holding one end of the cleaning tape, and the second reel holding other end of the cleaning tape.

In an embodiment, advancing the cleaning tape in the certain direction comprises advancing the cleaning tape in a horizontal direction.

### Advantageous Effects of Invention

According to the present invention, the substrate cleaning apparatus can clean the periphery of the substrate with a clean portion of the cleaning tape. In addition, the cleaning position can be arbitrarily changed by controlling the moving distance of the pressing structure, and the pressure applied from the pressing structure to the substrate can be controlled by controlling the pressure in the internal space of the pressing structure. As a result, the effect of cleaning the periphery of the substrate can be improved.

### BRIEF DESCRIPTION OF DRAWINGS

FIG. 1A is an enlarged cross-sectional view showing a periphery of a substrate;

FIG. 1B is an enlarged cross-sectional view showing a periphery of a substrate;

FIG. 2 is a plan view schematically showing an embodiment of a substrate cleaning apparatus;

FIG. 3 is a perspective view of the substrate cleaning apparatus shown in FIG. 2;

FIG. 4 is a view of a periphery cleaning unit as viewed from a direction indicated by arrow A in FIG. 2;

FIG. 5 is a schematic diagram of the periphery cleaning unit shown in FIGS. 2 to 4;

FIG. 6 is a view of a pressing structure as viewed from a direction indicated by arrow B in FIG. 5;

FIG. 7A is a diagram showing a state in which a cleaning tape is separated from a periphery of a wafer,

FIG. 7B is a diagram showing a state in which the cleaning tape is pressed against the periphery of the wafer by an elastic element;

FIG. 7C is a diagram showing a state in which the pressing structure is further moved radially inward from the state shown in FIG. 7B;

FIG. 8 is a schematic diagram showing another embodiment of the periphery cleaning unit;

FIG. 9 is a view of the periphery cleaning unit of FIG. 8 as viewed from a direction indicated by arrow C in FIG. 8;

FIG. 10A is a diagram showing a state in which a center line of a wafer in its thickness direction is located on a central portion of the pressing structure;

FIG. 10B is a diagram showing a state in which the pressing structure is lowered from the position shown in FIG. 10A;

FIG. 10C is a diagram showing a state in which the pressing structure is raised from the position shown in FIG. 10A;

FIG. 11 is a schematic diagram showing still another embodiment of the periphery cleaning unit;

FIG. 12 is a view of the periphery cleaning unit of FIG. 11 as viewed from a direction indicated by arrow D in FIG. 11;

FIG. 13 is a schematic diagram showing an embodiment of a tape cleaning mechanism;

FIG. 14 is a schematic diagram showing another embodiment of the tape cleaning mechanism;

FIG. 15 is a schematic diagram showing still another embodiment of the periphery cleaning unit;

FIG. 16 is a perspective view schematically showing another embodiment of the substrate cleaning apparatus;

FIG. 17 is a plan view schematically showing still another embodiment of the substrate cleaning apparatus;

FIG. 18 is a vertical cross-sectional view of the substrate cleaning apparatus shown in FIG. 17;

FIG. 19 is an enlarged view of a polishing head;

FIG. 20 is a diagram showing a polishing head when polishing a bevel portion of a wafer;

FIG. 21 is a schematic diagram showing still another embodiment of the periphery cleaning unit; and

FIG. 22 is a schematic diagram showing still another embodiment of the periphery cleaning unit.

### DESCRIPTION OF EMBODIMENTS

Hereinafter, embodiments of the present invention will be described with reference to the drawings. In the drawings described below, the same or corresponding components are denoted by the same reference numerals, and redundant descriptions are omitted.

In this specification, a periphery of a substrate is defined as a portion including a bevel portion located at an outermost edge of the substrate, and a top edge portion and a bottom edge portion located radially inwardly of the bevel portion.

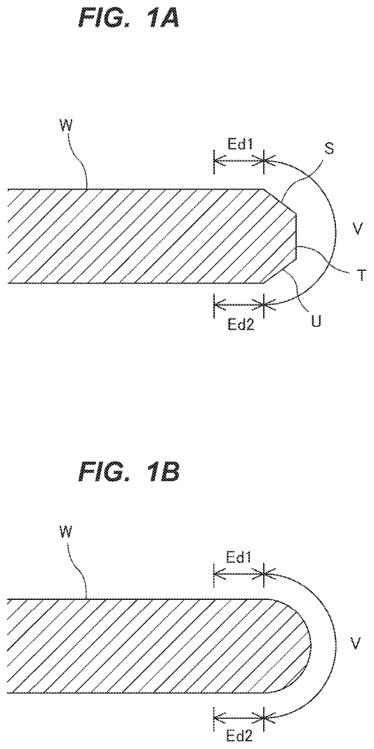

FIG. 1A and FIG. 1B are enlarged cross-sectional views showing a periphery of a substrate More specifically, FIG. 1A is a cross-sectional view of a so-called straight-type substrate, and FIG. 1B is a cross-sectional view of a so-called round-type substrate. In a wafer W (which is an example of the substrate) in FIG. 1A, the bevel portion is an outermost peripheral surface of the wafer W (indicated by symbol V) which includes an upper slope (or an upper bevel portion) S, a lower slope (or a lower bevel portion) U, and a side portion (apex) T. In a wafer W of FIG. 1B, the bevel portion is a portion (indicated by symbol V) having a curved cross section, which constitutes an outermost peripheral surface of the wafer W. The top edge portion is a flat portion Ed1 located radially inwardly of the bevel portion V. The bottom edge portion is a flat portion Ed2 located at the opposite side from the top edge portion and located radially inwardly of the bevel portion V. The top edge portion Ed1 may include a region where devices are formed.

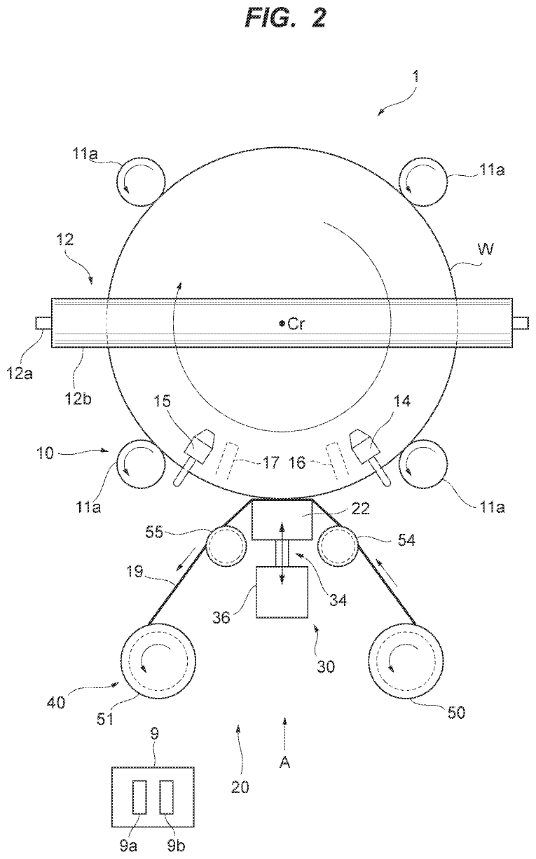

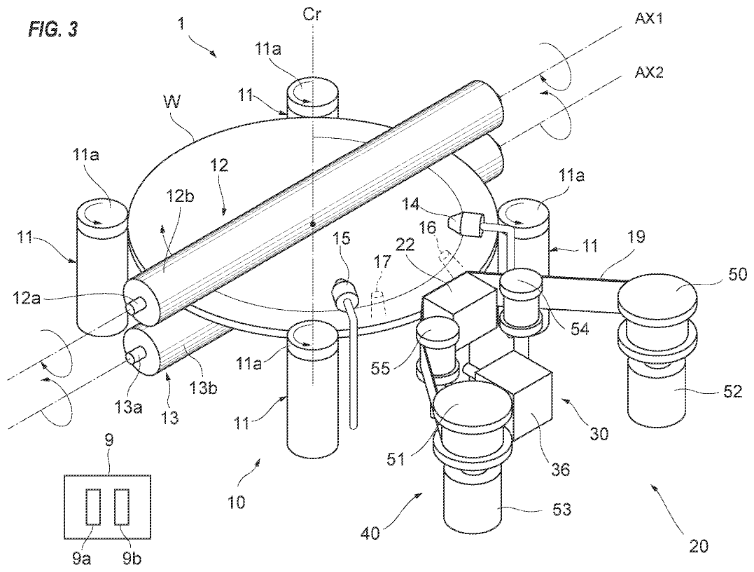

FIG. 2 is a plan view schematically showing an embodiment of a substrate cleaning apparatus, and FIG. 3 is a perspective view of the substrate cleaning apparatus shown in FIG. 2. As shown in FIGS. 2 and 3, a substrate cleaning apparatus 1 includes a substrate holder 10 configured to hold and rotate a wafer W (which is an example of a substrate), an upper roll cleaning member (e.g., a roll sponge) 12 rotatably supported by a first roll holder (not shown), a lower roll cleaning member (e.g., a roll sponge) 13 rotatably supported by a second roll holder (not shown), two upper liquid supply nozzles 14 and 15 for supplying liquid, as cleaning liquid, onto an upper surface of the wafer W, two lower liquid supply nozzles 16 and 17 for supplying liquid, as cleaning liquid, onto a lower surface of the wafer W, a periphery cleaning unit 20 configured to bring a cleaning tape 19 into contact with the periphery of the wafer W to clean the periphery of the wafer W, and an operation controller 9 configured to control operation of each component of the substrate cleaning apparatus 1. In the following description, the upper surface of the wafer W is a front surface (device surface) of the wafer W, and the lower surface is a back surface of the wafer W.

The substrate cleaning apparatus 1 of this embodiment can perform both cleaning of the upper and lower surfaces of the wafer W with the roll cleaning members 12 and 13 and cleaning of the periphery of the wafer W with the periphery cleaning unit 20. The substrate holder 10 includes a plurality of (four in this embodiment) spindles 11 configured to hold the periphery of the wafer W and horizontally rotate the wafer W, a spindle moving mechanism (not shown), and a substrate rotating mechanism (not shown). The plurality of spindles 11 are movable in directions (horizontal directions) toward and away from the wafer W by the spindle moving mechanism (e.g., air cylinder) not shown. The plurality of spindles 11 have a plurality of spin rollers 11a.

The substrate holder 10 holds the wafer W by positioning the periphery of the wafer W in a fitting groove formed in a circumferential surface of the spin roller 11a provided at an upper part of each spindle 11 and pressing the wafer W inward by the spin rollers 11a. The wafer W is horizontally rotated by the rotation of the spin rollers 11a. In this embodiment, two of the four spin rollers 11a are coupled to the substrate rotating mechanism (not shown), and these two spin rollers 11a are rotated in the same direction by the substrate rotating mechanism. The wafer W is rotated about its axis Cr by the rotation of the two spin rollers 11a while the wafer W is held by the four spin rollers 11a. Specifically, two of the four spin rollers 11a give a rotational force to the wafer W, and the other two spin rollers 11a act as bearings for receiving the rotation of the wafer W. In one embodiment, all the spin rollers 11a may be coupled to the substrate rotating mechanism to impart the rotational force to the wafer W.

The upper roll cleaning member 12 and the lower roll cleaning member 13 are columnar and elongated. The upper roll cleaning member 12 includes a columnar core material 12a and a cylindrical sponge member 12b fixed to an outer circumferential surface of the core material 12a. The lower roll cleaning member 13 includes a columnar core material 13a, and a cylindrical sponge member 13b fixed to an outer circumferential surface of the core material 13a. The sponge members 12b and 13b may be made of polyvinyl alcohol (PVA), for example.

The substrate cleaning apparatus 1 further includes a first roll cleaning member rotating mechanism (not shown) configured to rotate the upper roll cleaning member 12 about its axis AX1, and a second roll cleaning member rotating mechanism (not shown) configured to rotate the lower roll cleaning member 13 about its axis AX2. The roll cleaning members 12 and 13 are rotated in the directions indicated by arrows shown in FIG. 3 by the first and second roll cleaning member rotating mechanisms.

The substrate cleaning apparatus 1 includes a first elevating mechanism (not shown) configured to vertically move the upper roll cleaning member 12, the first roll holder, and the first roll cleaning member rotating mechanism, and a second elevating mechanism (not shown) configured to vertically move the second roll cleaning member 13, the second roll holder, and the second roll cleaning member rotating mechanism. Specifically, the upper roll cleaning member 12 can move up and down with respect to the upper surface of the wafer W, and the lower roll cleaning member 13 can move up and down with respect to the lower surface of the wafer W.

The upper liquid supply nozzles 14 and 15 are arranged above the wafer W held by the substrate holder 10, and the lower liquid supply nozzles 16 and 17 are arranged below the wafer W held by the substrate holder 10. The upper liquid supply nozzle 14 and the lower liquid supply nozzle 16 are nozzles for supplying rinsing liquid (for example, ultrapure water) to the upper surface and the lower surface of the wafer W, respectively. The upper liquid supply nozzle 15 and the lower liquid supply nozzle 17 are nozzles for supplying chemical liquid to the upper surface and the lower surface of the wafer W, respectively. The upper liquid supply nozzle 14 and the lower liquid supply nozzle 16 are coupled to a rinsing-liquid supply source (not shown), and the upper liquid supply nozzle 15 and the lower liquid supply nozzle 17 are coupled to a chemical-liquid supply source (not shown).

The operation controller 9 is electrically coupled to the substrate holder 10, the first and second roll cleaning member rotating mechanisms, the first and second elevating mechanisms, the lower liquid supply nozzles 16 and 17, and the upper liquid supply nozzles 14 and 15. The operations of the substrate holder 10, the first and second roll cleaning member rotating mechanisms, the first and second elevating mechanisms, the lower liquid supply nozzles 16 and 17, and the upper liquid supply nozzles 14 and 15 are controlled by the operation controller 9.

The operation controller 9 includes a memory 9a storing programs therein, and a processor 9b configured to execute arithmetic operations according to instructions included in the programs. The processor 9b includes a CPU (Central Processing Unit) or GPU (Graphic Processing Unit) that performs arithmetic operations according to the instructions included in the programs stored in the memory 9a. The memory 9a may include a main memory (e.g., random access memory) accessible by the processor 9b and an auxiliary memory (e.g., hard disk drive or solid state drive) for storing data and the programs. The operation controller 9 is composed of at least one computer. However, the specific configurations of the operation controller 9 are not limited to this example.

Next, processes of cleaning the upper and lower surfaces of the wafer W will be described. First, the substrate holder 10 horizontally holds the wafer W with its surface facing up, and rotates the wafer W about its axis Cr. Next, the rinsing liquid is supplied to the upper surface and the lower surface of the wafer W from the upper liquid supply nozzle 14 and the lower liquid supply nozzle 16, respectively, and the chemical liquid is supplied to the upper surface and the lower surface of the wafer W from the upper liquid supply nozzle 15 and the lower liquid supply nozzle 17, respectively. In this state, the upper roll cleaning member 12, which is being rotated about the axis AX1, is lowered to bring the sponge member 12b into contact with the upper surface of the rotating wafer W, while the lower roll cleaning member 13, which is being rotated about the axis AX2, is elevated to bring the sponge member 13b into contact with the lower surface of the rotating wafer W.

With these operations, the upper and lower surfaces of the wafer W are scrubbed with the roll cleaning members 12 and 13 in the presence of the cleaning liquid (i.e., the rinsing liquid and the chemical liquid). The roll cleaning members 12 and 13 are longer than the diameter of the wafer W so that the roll cleaning members 12 and 13 can come into contact with the entire upper and lower surfaces of the wafer W. In one embodiment, the cleaning process for the upper and lower surfaces of the wafer W described above is performed after the surface of the substrate is polished by chemical mechanical polishing (CMP).

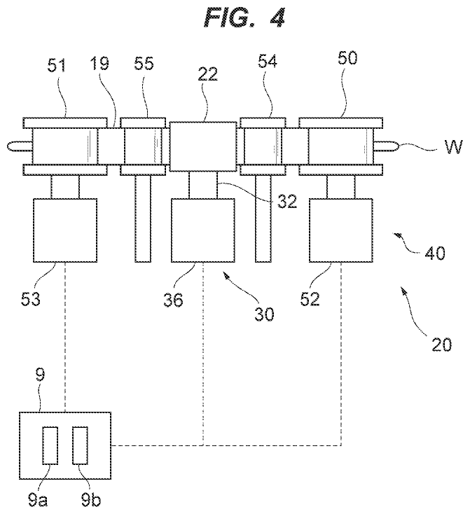

Next, details of the periphery cleaning unit 20 will be described. FIG. 4 is a view of the periphery cleaning unit 20 as viewed from a direction indicated by arrow A in FIG. 2. As shown in FIGS. 2 to 4, the periphery cleaning unit 20 includes a pressing structure 22 configured to press a cleaning tape 19 as a cleaning tool against the periphery of the wafer W to clean the periphery of the wafer W, a pressing-structure moving mechanism 30 configured to move the pressing structure 22 in the radial direction of the wafer W, and a tape advancing unit 40 configured to hold the cleaning tape 19 and advance the cleaning tape 19 in its longitudinal direction. In FIGS. 2 to 4, depictions of a fluid delivery line 42, a pressure regulator 44, a fluid supply source 46, and on-off valves 48a and 48b, which will be described later, are omitted

The tape advancing unit 40 includes a first reel 50 and a second reel 51 that hold both ends of the cleaning tape 19, and a first reel rotating motor 52 and a second reel rotating motor 53 configured to rotate the first reel 50 and the second reel 51, respectively. The first reel rotating motor 52 and the second reel rotating motor 53 are coupled to the first reel 50 and the second reel 51, respectively. The periphery cleaning unit 20 is arranged such that the pressing structure 22 is located between two of the four spindles 11.

The pressing structure 22 faces the periphery of the wafer W when the wafer W is held by the substrate holder 10. The cleaning tape 19 extends from the first reel 50 to the second reel 51 via the pressing structure 22 such that a cleaning surface of the cleaning tape 19 faces the periphery of the wafer W. A back side of the cleaning tape 19 (a surface opposite to the cleaning surface) is supported by the pressing structure 22.

A first guide roller 54 is arranged between the first real 50 and the pressing structure 22, and a second guide roller 55 is arranged between the second reel 51 and the pressing structure 22. The guide rollers 54 and 55 support the cleaning tape 19 extending between the reels 50 and 51 and the pressing structure 22. When the tape advancing unit 40 is in motion, the cleaning tape 19 advances in a certain direction.

In this embodiment, the reel rotating motors 52 and 53 rotate the reels 50 and 51 in the directions of the arrows shown in FIG. 2, so that the cleaning tape 19 is pulled out from the first reel 50 and is taken up by the second reel 51. With a predetermined tension exerted to the cleaning tape 19, the cleaning tape 19 advances from the first reel 50 to the second reel 51 via the first guide roller 54, the pressing structure 22, and the second guide roller 55 in this order. The reels 50, 51 and the reel rotating motors 52, 53 are arranged such that the cleaning tape 19 advances in the horizontal direction (the tangential direction of the wafer W). With this arrangement, the tape advancing unit 40 can be made compact.

The tape advancing unit 40 is configured to be able to advance the cleaning tape 19 in a direction opposite to the direction from the first reel 50 to the second reel 51. Specifically, when the reel rotating motors 52 and 53 rotate the reels 50 and 51 in directions opposite to the directions of the arrows shown in FIG. 2, the cleaning tape 19 is pulled out from the second reel 51 and is taken up by the first reel 50. With a predetermined tension exerted to the cleaning tape 19, the cleaning tape 19 advances from the second reel 51 to the first reel 50 via the second guide roller 55, the pressing structure 22, and the first guide roller 54 in this order

In one embodiment, the tape advancing unit 40 may include a tape advancing mechanism configured to advance the cleaning tape 19 from the first reel 50 to the second reel 51 (or from the second reel 51 to the first reel 50). The tape advancing mechanism includes a tape advancing roller, a tape gripping roller arranged next to the tape advancing roller, and a motor coupled to the tape advancing roller. In an embodiment in which the tape advancing unit 40 includes a tape advancing mechanism, the cleaning tape 19 is sandwiched between the tape advancing roller and the tape gripping roller In one embodiment, the tape advancing unit 40 rotates the tape advancing roller by the motor coupled to the tape advancing roller, thereby advancing the cleaning tape 19 from the first reel 50 (or the second reel 51) to the second reel 51 (or the first reel 50) via the pressing structure 22. The first reel 50 and the second reel 51 may be rotated in opposite directions to apply a predetermined tension to the cleaning tape 19.

The tape advancing unit 40 is electrically coupled to the operation controller 9. The operation of the tape advancing unit 40 is controlled by the operation controller 9. Examples of the cleaning tape 19 include a tape made of nonwoven fabric and a tape made of sponge In one embodiment, the cleaning tape 19 may have abrasive grains, such as silica (SiO₂), on its surface (cleaning surface). This allows the cleaning tape 19 to have a light polishing effect.

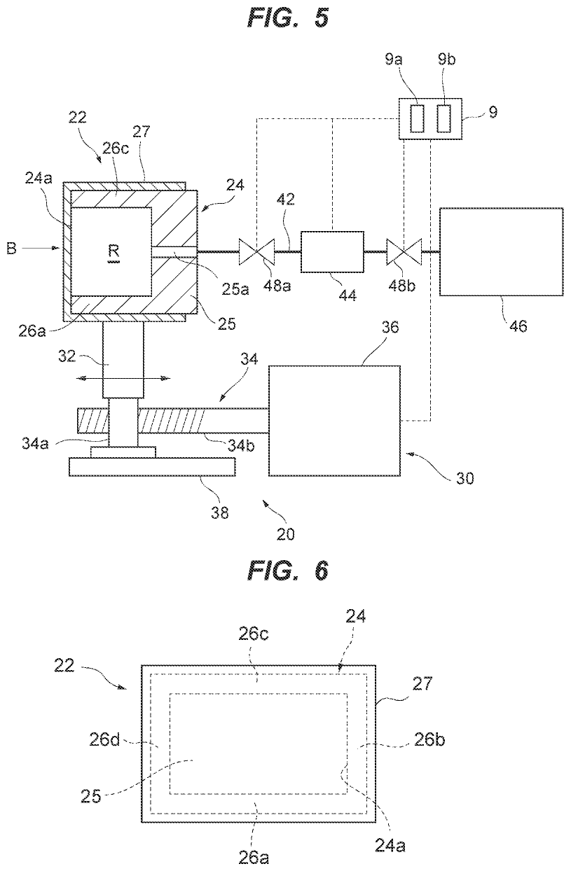

FIG. 5 is a schematic diagram of the periphery cleaning unit 20 shown in FIGS. 2 to 4, and FIG. 6 is a diagram of the pressing structure 22 as viewed from a direction indicated by arrow B in FIG. 5. In FIG. 5, the tape advancing unit 40 and the guide rollers 54 and 55 are not depicted. As shown in FIGS. 5 and 6, the pressing structure 22 includes a hollow support member 24 and an elastic element 27 configured to support the cleaning tape 19. The pressing structure 22 has an internal space R, and the support member 24 has an opening 24a that is open toward the wafer W. The support member 24 bas a base 25 and a plurality of protrusions 26a, 26b, 26c, 26d extending in directions perpendicular to the base 25. The base 25 and the protrusions 26a, 26b, 26c, 26d are arranged so as to surround the internal space R. The base 25 and the protrusions 26a, 26b, 26c, 26d are integrally formed.

The elastic element 27 is arranged to close the opening 24a and is in contact with ends of the protrusions 26a, 26b, 26c and 26d. More specifically, the elastic element 27 is stretched between the ends of the protrusions 26a, 26b, 26c, and 26d. The internal space R is formed in the pressing structure 22 by the support member 24 and the elastic element 27. The support member 24 is a rigid structure, and the elastic element 27 is made of elastic rubber or the like. In one embodiment, the surface of the elastic element 27 may be coated to ensure a sliding property with the cleaning tape 19.

The pressing-structure moving mechanism 30 is configured to be able to control a position of the pressing structure 22 in the radial direction of the wafer W (i.e., control a movement distance of the pressing structure 22 from a predetermined reference position). The pressing-structure moving mechanism 30 is electrically coupled to the operation controller 9, and the operation of the pressing-structure moving mechanism 30 is controlled by the operation controller 9. The operation controller 9 is configured to instruct the pressing-structure moving mechanism 30 to control the position of the pressing structure 22. Specifically, the operation controller 9 transmits a target value of the position of the pressing structure 22 (or a target value of the movement distance) to the pressing-structure moving mechanism 30, and the pressing-structure moving mechanism 30 moves the pressing structure 22 to a target position according to the target value.

The pressing structure 22 is coupled to the pressing-structure moving mechanism 30 via a fixing member 32. The pressing-structure moving mechanism 30 includes a ball screw mechanism 34 and a motor 36 configured to actuate the ball screw mechanism 34. The ball screw mechanism 34 includes a nut device 34a fixed to the fixing member 32 and a screw shaft 34b screwed into the nut device 34a. The screw shaft 34b is coupled to the motor 36. In this embodiment, the motor 36 is a servomotor. In one embodiment, a stepping motor may be used as the motor 36.

The operation controller 9 instructs the pressing-structure moving mechanism 30 to rotate the motor 36, which in turn rotates the screw shaft 34b. As a result, the pressing structure 22 moves toward or away from the wafer W via the nut device 34a and the fixing member 32. The movement of the nut device 34a is guided by a linear guide 38. The motor 36 rotates the screw shaft 34b until the pressing structure 22 is located at the target position, so that the movement distance of the pressing structure 22 can be controlled. In one embodiment, the pressing-structure moving mechanism 30 may be a combination of an air cylinder and a pressure regulator.

As shown in FIG. 5, the periphery cleaning unit 20 further includes a fluid delivery line 42 and a pressure regulator 44 for controlling the pressure in the internal space R. An internal passage 25a is formed in the base 25 of the support member 24. One end of the fluid delivery line 42 is coupled to the internal passage 25a, and the other end is coupled to a fluid supply source 46. The fluid delivery line 42 communicates with the internal space R through the internal passage 25a. A fluid, such as gas (air, nitrogen, etc.) or liquid (water, etc.), is supplied from the fluid supply source 46 to the internal space R through the fluid delivery line 42 and the internal passage 25a.

The pressure regulator 44 is coupled to the fluid delivery line 42. On-off valves 48a and 48b are further coupled to the fluid delivery line 42. When the on-off valves 48a, 48b are opened, the fluid is supplied from the fluid supply source 46 to the internal space R through the pressure regulator 44 and the on-off valves 48a, 48b.

The operation controller 9 is electrically coupled to the pressure regulator 44 and the on-off valves 48a and 48b, and the operations of the pressure regulator 44 and the on-off valves 48a and 48b are controlled by the operation controller 9. The operation controller 9 is configured to instruct the pressure regulator 44 to regulate the pressure in the internal space R. Specifically, the operation controller 9 transmits a predetermined target pressure value to the pressure regulator 44, and the pressure regulator 44 regulates the pressure of the fluid in the internal space R such that the pressure in the internal space R has the target pressure value. The pressure regulator 44 can control the pressure in the internal space R by regulating the pressure of the fluid in the internal space R. An example of the pressure regulator 44 is an electro-pneumatic regulator.

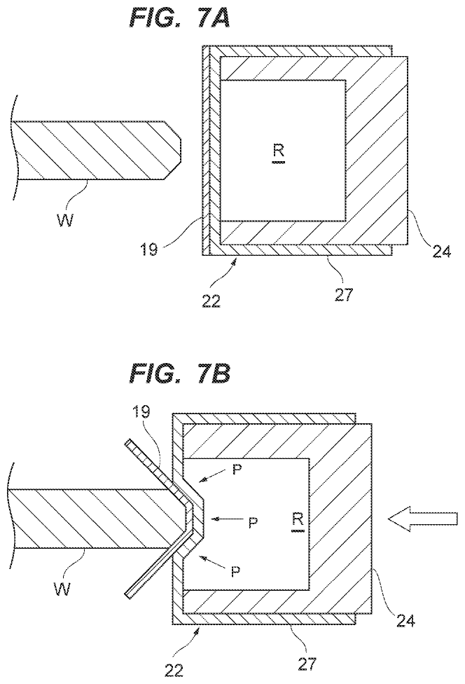

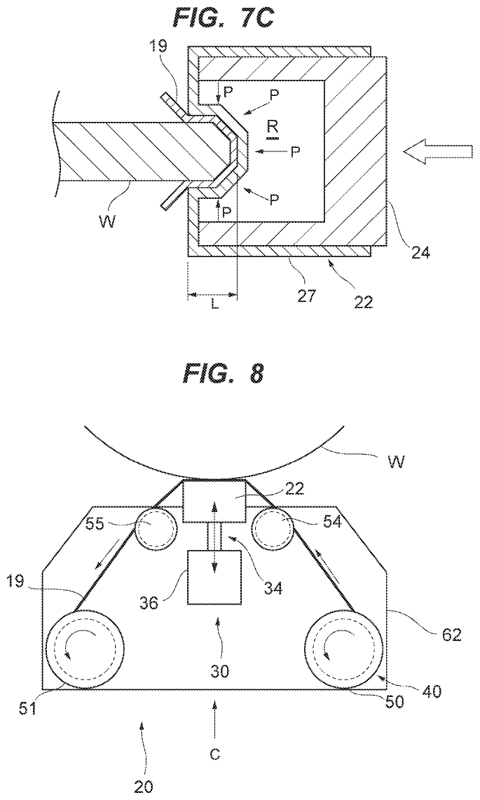

FIGS. 7A to 7C are diagrams showing how the cleaning tape 19 is pressed against the periphery of the wafer W by the pressing structure 22. FIGS. 7A to 7C show an example of cleaning the so-called straight-type wafer W (see FIG. 1A). The operation controller 9 drives the pressing-structure moving mechanism 30 from a state in which the cleaning tape 19 is separated from the periphery of the wafer W (see FIG. 7A) until the cleaning tape 19 contacts the periphery of the wafer W. The pressing structure 22 is moved toward the wafer W. As a result, the cleaning tape 19 is pressed against the periphery of the wafer W by the elastic member 27 (see FIG. 7B). The pressing structure 22 presses the wafer W via the cleaning tape 19, so that the elastic element 27 deforms along the shape of the wafer W.

The cleaning tape 19 is pressed against the periphery of the wafer W while the wafer W is rotated and the cleaning tape 19 is advanced at a predetermined speed, so that the periphery of the wafer W is cleaned with the cleaning tape 19. According to this embodiment, the substrate cleaning apparatus 1 can clean the periphery of the wafer W with a clean portion of the cleaning tape 19 at all times. In addition, since the cleaning tape 19 is pressed against the periphery of the wafer W so as to wrap the periphery of the wafer W, the periphery of the wafer W can be cleaned without tilting the pressing structure 22 by a tilting mechanism or the like. According to the configuration of this embodiment, the periphery cleaning unit 20 can be made compact.

During cleaning of the wafer W, the internal space R is supplied with the fluid and the internal space R is pressurized. As a result, a pressure P is applied to the back surface of the elastic element 27. This pressure P presses the elastic element 27 against the wafer W via the cleaning tape 19. As a result, the cleaning tape 19 can be positively conformed to the shape of the periphery of the wafer W. Furthermore, the pressure regulator 44 regulates the pressure in the internal space R, so that the pressure applied to the wafer W can be controlled. Therefore, the pressure applied to the wafer W can be kept constant, and a variation in pressure due to the contact position between the cleaning tape 19 and the wafer W can be reduced.

As shown in FIG. 7C, the pressing structure 22 may be further moved radially inward from the state shown in FIG. 7B. As a result, the elastic element 27 is further pressed against the wafer W, so that the elastic element 27 and the cleaning tape 19 are further deformed along the shape of the periphery of the wafer W. The pressing-structure moving mechanism 30 can control a pressing amount L of the pressing structure 22 by regulating the position of the pressing structure 22 in the radial direction of the wafer W. The pressing amount L corresponds to a distance from an innermost surface of the elastic element 27 in the radial direction of the wafer W to an outermost surface of the elastic element 27 pressed against the outermost edge of the wafer W (i.e., the side portion of the bevel portion in the example shown in FIG. 7C) via the cleaning tape 19.

FIG. 7C shows an example in which the elastic element 27 is pushed until the cleaning tape 19 contacts the top edge portion and the bottom edge portion (see FIG. 1A). In this way, controlling the pressing amount L can allow for a change in the contact position of the cleaning tape 19 and the wafer W (i.e., the cleaning position). The cleaning tape 19 can clean not only the entire bevel portion, but also the top edge portion and the bottom edge portion.

As described above, during cleaning of the periphery of the wafer W, the internal space R is pressurized. When the internal space R is pressurized, a force that pushes the base 25 in the radially outward direction of the wafer W is applied from the internal space R to the pressing structure 22. The pressing-structure moving mechanism 30 uses the motor, such as a servomotor or a stepping motor, that can precisely control the rotational position or rotational angle of the rotating shaft of the motor. Therefore, the pressing-structure moving mechanism 30 can precisely control the position of the pressing structure 22 without being affected by the pressure in the internal space R.

In this embodiment, the cleaning tape 19 advances in the horizontal direction (the tangential direction of the wafer W). In one embodiment, the tape advancing unit 40 may be arranged to advance the cleaning tape 19, supported on the pressing structure 22, in the vertical direction (i.e., in a direction perpendicular to the tangential direction of the wafer W). In this case, the first reel 50 and the second reel 51 are arranged vertically.

Next, the process of cleaning the periphery of the wafer W will be described. First, the substrate holder 10 horizontally holds the wafer W with its surface facing up, and rotates the wafer W about its axis Cr. Next, the rinsing liquid is supplied to the upper surface and the lower surface of the wafer W from the upper liquid supply nozzle 14 and the lower liquid supply nozzle 16, respectively, and the chemical liquid is supplied to the upper surface and the lower surface of the wafer W from the upper liquid supply nozzle 15 and the lower liquid supply nozzle 17, respectively. The rinsing liquid and the chemical liquid spread outwardly on the wafer W due to centrifugal force until the rinsing liquid and the chemical liquid are supplied to the periphery of the wafer W. The periphery of the wafer W is cleaned in the presence of the rinsing liquid and the chemical liquid.

In this state, the operation controller 9 drives the tape advancing unit 40 to advance the cleaning tape 19 at a predetermined speed in a certain direction (i.e., the direction from the first reel 50 to the second reel 51 in this embodiment) while a predetermined tension is applied to the cleaning tape 19. More specifically, the tape advancing unit 40 advances the cleaning tape 19 in the horizontal direction (the tangential direction of the wafer W).

In this state, the pressing-structure moving mechanism 30 moves the pressing structure 22 toward the wafer W to bring the pressing structure 22 into contact with the wafer W. Specifically, the operation controller 9 transmits a target value of the position of the pressing structure 22 in the radial direction of the wafer W to the pressing-structure moving mechanism 30. The pressing-structure moving mechanism 30 in turn moves the pressing structure 22 to the target position according to the target value. The pressing-structure moving mechanism 30 controls the position of the pressing structure 22 in the radial direction of the wafer W according to the target value. The pressing structure 22 presses the cleaning tape 19 against the periphery of the wafer W to clean the periphery of the wafer W.

During the cleaning operation, the operation controller 9 instructs the pressure regulator 44 to control the pressure in the internal space R. Specifically, the operation controller 9 opens the on-off valves 48a and 48b to supply the fluid, such as gas (air, nitrogen, etc.) or liquid (water, etc.), from the fluid supply source 46 into the internal space R. Then, the operation controller 9 instructs the pressure regulator 44 to regulate the pressure of the fluid in the internal space R such that the pressure in the internal space R becomes the target pressure value.

In one embodiment, the process of cleaning the periphery of the wafer W described above is performed after the periphery of the substrate is polished. In one embodiment, the process of cleaning the periphery of the wafer W may be performed simultaneously with the process of cleaning the upper and lower surfaces of the wafer W described above, or may be performed separately.

In this embodiment, the periphery of the wafer W is cleaned while the cleaning tape 19 advances in one direction, so that the periphery of the wafer W can be cleaned with a clean portion of the cleaning tape 19 at all times. Furthermore, the cleaning position can be arbitrarily changed by controlling the movement distance of the pressing structure 22, and the pressure applied from the pressing structure 22 to the wafer W can be changed by controlling the pressure in the internal space R of the pressing structure 22. As a result, the effect of cleaning the periphery of the wafer W can be improved.

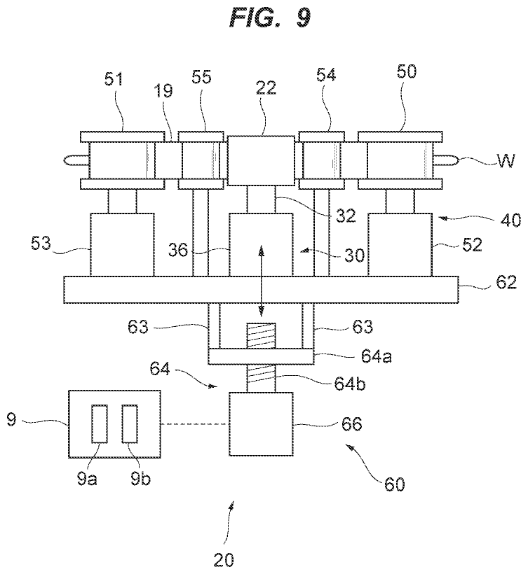

FIG. 8 is a schematic diagram showing another embodiment of the periphery cleaning unit 20, and FIG. 9 is a view of the periphery cleaning unit 20 in FIG. 8 as viewed from a direction indicated by arrow C in FIG. 8. Details of the present embodiment, which will not be specifically described, are the same as those of the embodiments described with reference to FIGS. 1A to 7C, and redundant descriptions thereof will be omitted. In FIGS. 8 and 9, depictions of the fluid delivery line 42, the pressure regulator 44, the fluid supply source 46, and the on-off valves 48a, 48b are omitted. As shown in FIG. 9, the periphery cleaning unit 20 of this embodiment further includes a vertically-moving mechanism 60 configured to vertically move the pressing structure 22.

As shown in FIGS. 8 and 9, the periphery cleaning unit 20 of this embodiment further includes a base plate 62. The pressing-structure moving mechanism 30, the tape advancing unit 40, and the guide rollers 54 and 55 are secured to an upper surface of the base plate 62. The vertically-moving mechanism 60 is coupled to the base plate 62. In this embodiment, the vertically-moving mechanism 60 is configured to vertically move the base plate 62, the pressing structure 22, the pressing-structure moving mechanism 30, the tape advancing unit 40, and the guide rollers 54 and 55 together.

The vertically-moving mechanism 60 is configured to be able to change the position of the pressing structure 22 in the vertical direction (i.e., the movement distance of the pressing structure 22 in the vertical direction). The vertically-moving mechanism 60 is electrically coupled to the operation controller 9, and the operation of the vertically-moving mechanism 60 is controlled by the operation controller 9.

The base plate 62 is coupled to the vertically-moving mechanism 60 via a plurality of fixing members 63. The vertically-moving mechanism 60 includes a ball screw mechanism 64 and a motor 66 configured to actuate the ball screw mechanism 64. The ball screw mechanism 64 includes a nut device 64a fixed to the plurality of fixing members 63 and a screw shaft 64b screwed into the nut device 64a. The screw shaft 64b is coupled to the motor 66. Examples of motor 66 include servomotor and stepping motor.

The operation controller 9 instructs the vertically-moving mechanism 60 to rotate the motor 66, thereby rotating the screw shaft 64b. As a result, the base plate 62, the pressing structure 22, the pressing-structure moving mechanism 30, the tape advancing unit 40, and the guide rollers 54 and 55 move up and down via the nut device 64a and the fixing member 63. The vertical movement of the nut device 64a is guided by a linear guide (not shown). The motor 66 controls the vertical movement distance of the pressing structure 22 by rotating the ball screw shaft 64b such that the pressing structure 22 moves by a predetermined distance. In one embodiment, the vertically-moving mechanism 60 may be a combination of an air cylinder and a pressure regulator.

In this embodiment, the periphery of the wafer W is cleaned while the base plate 62, the pressing structure 22, the pressing-structure moving mechanism 30, the tape advancing unit 40, and the guide rollers 54 and 55 are vertically moved.

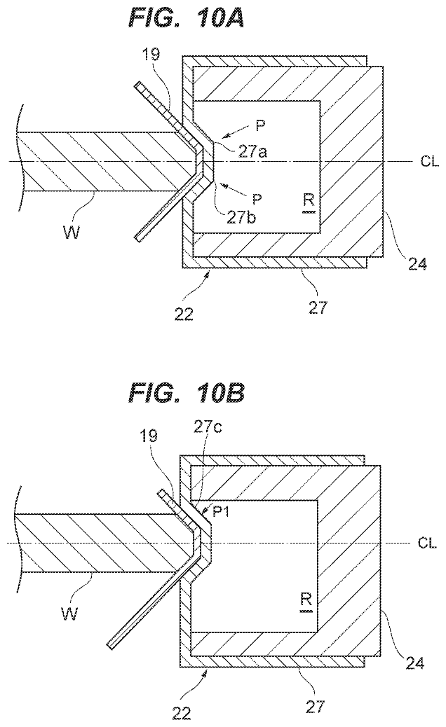

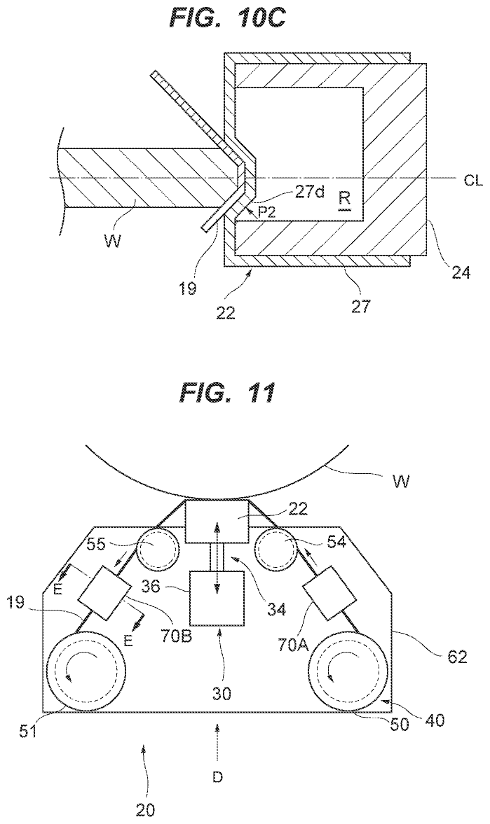

FIGS. 10A to 10C are diagrams showing the cleaning tape 19 and the wafer W in contact with each other when the pressing structure 22 is vertically moved. FIGS. 10A to 10C show an example of cleaning a so-called straight-type wafer W (see FIG. 1A). FIG. 10A is a diagram showing a state in which the center line CL of the wafer W in its thickness direction is located at the central portion of the pressing structure 22, FIG. 10B is a diagram showing a state in which the pressing structure 22 is lowered from the position shown in FIG. 10A, and FIG. 10C is a diagram showing a state in which the pressing structure 22 is elevated from the position shown in FIG. 10A

As shown in FIG. 10A, when the internal space R is pressurized with the center line CL positioned at the center of the pressing structure 22 and the cleaning tape 19 is pressed against the periphery of the wafer W, the pressure P on the back surface of the elastic element 27 may be concentrated on corners 27a and 27b of the elastic element 27. This may result in insufficient pressure on the upper and lower slopes of the bevel (see FIG. 1A).

When the pressing structure 22 is lowered until the center line CL is located at an upper part of the pressing structure 22 while the cleaning tape 19 is pressed against the periphery of the wafer W, the upper part of the elastic element 27 is pushed by the wafer W (see FIG. 10B). As a result, the pressure P1 applied to an upper inclined portion 27c of the elastic element 27 increases. As a result, sufficient pressure can be applied to the upper slope of the bevel portion of the wafer W.

When the pressing structure 22 is elevated until the center line CL is located at a lower part of the pressing structure 22 while the cleaning tape 19 is pressed against the periphery of the wafer W, the lower part of the elastic element 27 is pushed by the wafer W (see FIG. 10C). As a result, the pressure P2 applied to a lower inclined portion 27d of the elastic element 27 increases. As a result, sufficient pressure can be applied to the lower slope of the bevel portion.

The periphery of the wafer W can be cleaned while the pressing structure 22 is moving up and down. The cleaning tape 19 slides on the periphery of the wafer W in the vertical direction, which enables more positive cleaning. As a result, the cleaning effect can be further improved by moving the pressing structure 22 up and down when cleaning the periphery of the wafer W.

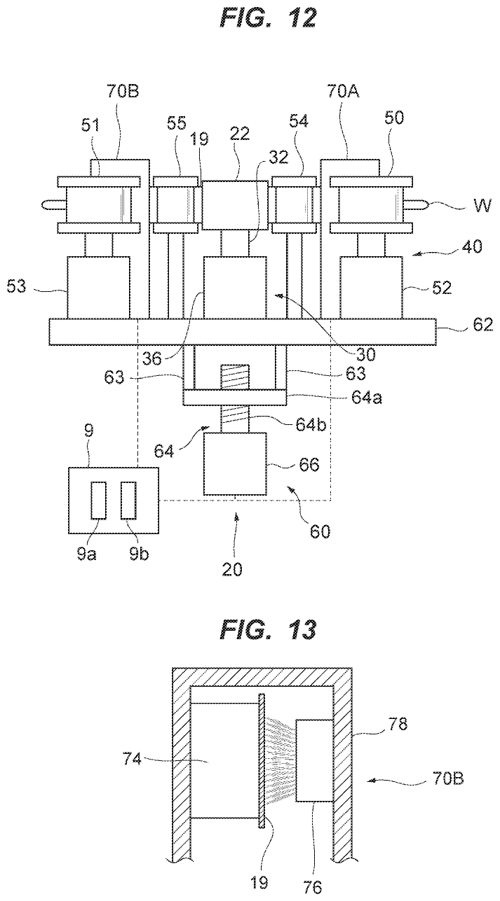

FIG. 11 is a schematic diagram showing still another embodiment of the periphery cleaning unit 20, and FIG. 12 is a view of the periphery cleaning unit 20 of FIG. 11 as viewed from a direction indicated by arrow D in FIG. 11. Details of this embodiment, which will not be specifically described, are the same as those of the embodiments described with reference to FIGS. 8 to 10C, and their repetitive descriptions will be omitted. The periphery cleaning unit 20 of this embodiment further includes tape cleaning mechanisms 70A and 70B for cleaning the cleaning tape 19. In FIGS. 11 and 12, the depictions of the fluid delivery line 42, the pressure regulator 44, the fluid supply source 46, and the on-off valves 48a, 48b are omitted.

The tape cleaning mechanisms 70A and 70B are arranged in the path of the cleaning tape 19 so as to surround the cleaning tape 19. Specifically, the tape cleaning mechanism 70A is arranged between the first reel 50 and the pressing structure 22, and the tape cleaning mechanism 70B is arranged between the second reel 51 and the pressing structure 22. The tape cleaning mechanisms 70A and 70B are configured such that the cleaning tape 19 passes through them. The tape cleaning mechanisms 70A and 70B are electrically coupled to the operation controller 9, and operations of the tape cleaning mechanisms 70A and 70B are controlled by the operation controller 9.

FIG. 13 is a schematic diagram showing one embodiment of the tape cleaning mechanism 70B, and is a cross-sectional view taken along line E-E of FIG. 11. The tape cleaning mechanisms 70A and 70B have the same configuration. The following descriptions relate to the tape cleaning mechanism 70B, but apply to the tape cleaning mechanism 70A as well. In the following descriptions, the tape cleaning mechanisms 70A and 70B may be collectively referred to simply as tape cleaning mechanism 70.

As shown in FIG. 13, the tape cleaning mechanism 70B includes a tape support member 74 configured to support the back side of the cleaning tape 19, a cleaning-liquid supply nozzle 76 configured to supply cleaning liquid to the front surface (i.e., the cleaning surface) of the cleaning tape 19, and a casing 78 accommodating the tape support member 74 and the cleaning-liquid supply nozzle 76. The tape support member 74 and the cleaning-liquid supply nozzle 76 are fixed to an inner surface of the casing 78. The casing 78 has a plurality of openings (not shown) through which the cleaning tape 19 passes. The cleaning-liquid supply nozzle 76 is arranged so as to face the front surface of the cleaning tape 19. An example of the cleaning liquid is pure water. The cleaning-liquid supply nozzle 76 is coupled to a cleaning-liquid supply source (not shown).

In this embodiment, the tape cleaning mechanism 70 cleans the cleaning tape 19 (the cleaning tape 19 that has been used for cleaning of the periphery of the wafer W) after the cleaning tape 19 has come into contact with the periphery of the wafer W. In one embodiment, while the wafer W is being cleaned, the cleaning tape 19 is cleaned. Specifically, the periphery of the wafer W is cleaned while the cleaning tape 19 is being advanced from the first reel 50 to the second reel 51. During cleaning of the periphery of the wafer W, the cleaning tape 19 moves from the first reel 50 to the second reel 51 via the tape cleaning mechanism 70A, the first guide rollers 54, the pressing structure 22, the second guide roller 55, and the tape cleaning mechanism 70B in this order. The operation controller 9 instructs the tape cleaning mechanism 70B to supply the cleaning liquid to the cleaning tape 19 that has come into contact with the periphery of the wafer W. As a result, the cleaning tape 19 that has come into contact with the periphery of the wafer W is cleaned. The cleaning tape 19 that has been cleaned by the tape cleaning mechanism 70B is collected on the second reel 51.

The cleaning tape 19 is cleaned while its back side is supported by the tape support member 74. Since the cleaning tape 19 is cleaned while the back side of the cleaning tape 19 supported by the tape support member 74, the cleaning tape 19 is prevented from fluttering during cleaning of the cleaning tape 19.

The cleaning liquid washes away foreign matter (particles), such as polishing debris adhering to the front surface of the cleaning tape 19 as a result of contact with the wafer W. In this manner, the cleaning tape 19 is cleaned while the periphery of the wafer W is being cleaned. The cleaning tape 19 that has been cleaned can be used for cleaning of the periphery of the wafer W again.

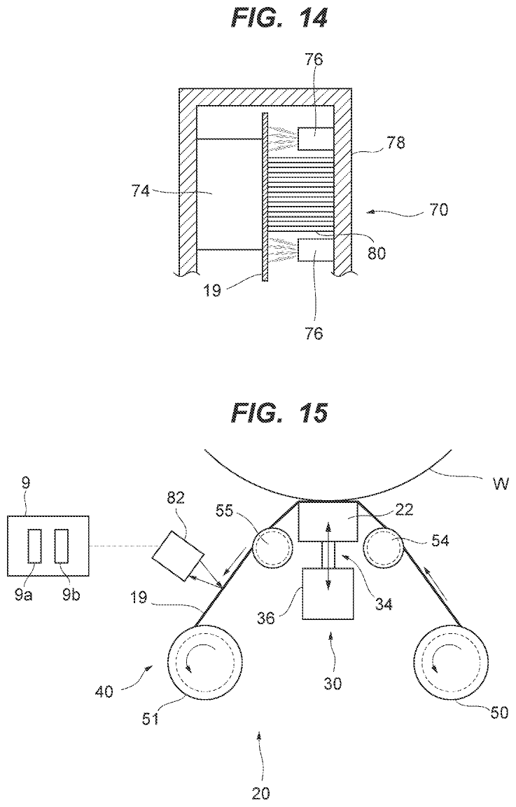

FIG. 14 is a schematic diagram showing another embodiment of the tape cleaning mechanism 70. Details of this embodiment, which will not be particularly described, are the same as those of the embodiments described with reference to FIG. 13, and their repetitive descriptions will be omitted. As shown in FIG. 14, the tape cleaning mechanism 70 of this embodiment further includes a plurality of cleaning-liquid supply nozzles 76 and a cleaning brush 80 arranged to contact the front surface (i.e., the cleaning surface) of the cleaning tape 19 to clean the cleaning tape 19. The cleaning brush 80 contacts the front surface of the cleaning tape 19 while the cleaning tape is advancing in a certain direction and the cleaning liquid is being supplied onto the front surface of the cleaning tape 19. As a result, the cleaning effect of the cleaning tape 19 can be improved.

In one embodiment, after the cleaning tape 19 is completely wound on the second reel 51, the tape advancing unit 40 may advance the cleaning tape 19 in the opposite direction while the cleaning tape 19 is cleaning the periphery of the wafer W. In this embodiment, during cleaning of the periphery of the wafer W, the cleaning tape 19 moves from the second reel 51 to the first reel 50 via the tape cleaning mechanism 70B, the second guide roller 55, the pressing structure 22, the first guide roller 54, and the tape cleaning mechanism 70A in this order. The details of the cleaning process for the periphery of the wafer W in this embodiment are the same as those described above, except for the moving direction of the cleaning tape 19. In one embodiment, the cleaning process of the cleaning tape 19 may be performed while the periphery of the wafer W is being cleaned. Specifically, the operation controller 9 instructs the tape cleaning mechanism 70A to supply the cleaning liquid onto the cleaning tape 19 that has come into contact with the periphery of the wafer W. As a result, the cleaning tape 19 that has come into contact with the periphery of the wafer W is cleaned. The cleaning tape 19 cleaned by the tape cleaning mechanism 70A is collected on the first reel 50.

Furthermore, in one embodiment, after the cleaning tape 19 is completely wound on the first reel 50, the cleaning tape 19 may be advanced in the opposite direction (i.e., the direction from the first reel 50 to the second reel 51) to clean the periphery of the wafer W. The cleaning tape 19 may be cleaned while the periphery of the wafer W is being cleaned.

In this way, after the cleaning tape 19 that has been cleaned is completely wound on either the first reel 50 or the second reel 51, the cleaning tape 19 may be advanced in the opposite direction. The cleaning tape 19 can be used again for cleaning of the periphery of the wafer W, so that a replacement frequency of the cleaning tape 19 can be reduced. Furthermore, the pressing structure 22 may be moved up and down during cleaning of the periphery of the wafer W, so that the replacement frequency of the cleaning tape 19 can be further reduced.

Furthermore, in one embodiment, the cleaning process for the cleaning tape 19 may be performed after peripheries of a predetermined number wafers W are cleaned. In this embodiment, after peripheries of a predetermined number of wafers W have been cleaned, the tape advancing unit 40 advances the cleaning tape 19 in one direction (e.g., the direction from the first reel 50 to the second reel 51, or the direction from the second reel 51 to the first reel 50), while the operation controller 9 instructs the tape cleaning mechanism 70A and/or the tape cleaning mechanism 70B to supply the cleaning liquid from the cleaning-liquid supply nozzle 76 onto the cleaning tape 19 that has contacted the periphery of the wafer W. The advancing direction of the cleaning tape 19 during the cleaning of the cleaning tape 19 in this embodiment is opposite to the advancing direction of the cleaning tape 19 during the cleaning process of the periphery of the wafer W that has been performed before the cleaning process of the cleaning tape 19. As a result, the cleaning tape 19 that has come into contact with the periphery of the wafer W is cleaned. In this embodiment also, after the cleaning tape 19 is completely wound on the first reel 50 or the second reel 51, the cleaning tape 19 may be advanced in the opposite direction by the tape advancing unit 40 so as to clean the periphery of the wafer W.

The embodiments described with reference to FIGS. 11 to 14 are applicable to the embodiments described with reference to FIGS. 1A to 7C. Furthermore, in one embodiment, the substrate cleaning apparatus 1 may include either the tape cleaning mechanism 70A or the tape cleaning mechanism 70B.

FIG. 15 is a schematic diagram showing still another embodiment of the periphery cleaning unit 20. Details of the present embodiment, which will not be specifically described, are the same as those of the embodiments described with reference to FIGS. 1A to 7C, and redundant descriptions thereof will be omitted. The periphery cleaning unit 20 of the present embodiment further includes a sensor 82 configured to direct light onto the cleaning tape 19 that has been brought into contact with the periphery of the wafer W after cleaning of the periphery of the wafer W and receive reflected light from the cleaning tape 19. In FIG. 15, the depictions of the fluid delivery line 42, the pressure regulator 44, the fluid supply source 46, and the on-off valves 48a and 48b are omitted.

The sensor 82 is arranged so as to face the front surface of the cleaning tape 19 that has been brought into contact with the periphery of the wafer W. The sensor 82 is configured to receive the reflected light from the cleaning tape 19 and measure intensity of the reflected light. The sensor 82 is, for example, an RGB color sensor. The RGB color sensor emits white LED light, separates the reflected light into three primary colors of red, green, and blue with a filter, and determines a color ratio with a detection element based on the intensity of each color of red, green, and blue. The sensor 82 may include an LED that can emit light in an UV (ultraviolet) range as a light source, and may further include a phosphor detection UV sensor as a light receiving sensor to measure the intensity of received light.

The sensor 82 is electrically coupled to the operation controller 9. The operation controller 9 receives a signal from the sensor 82 while the periphery of the wafer W is being cleaned, and compares the intensity of the reflected light received by the sensor 82 with a preset value. When the intensity of the reflected light is below the preset value, the operation controller 9 determines that the cleaning tape 19 is dirty and that the periphery of the wafer W is dirty. When the intensity of the reflected light is above the preset value, the operation controller 9 determines that the cleaning tape 19 is not dirty and that the periphery of the wafer W is not dirty. The operation controller 9 determines an end point of the cleaning process for the periphery of the wafer W based on a point in time when it is determined that the periphery of the wafer W is not dirty. This embodiment can be applied to the embodiments described with reference to FIGS. 8 to 14 as well.

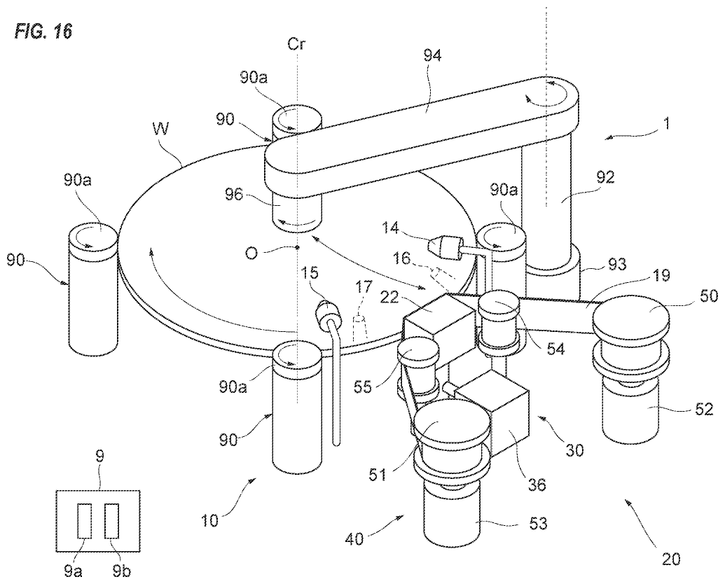

FIG. 16 is a perspective view schematically showing another embodiment of the substrate cleaning apparatus 1. Details of this embodiment, which will not be specifically described, are the same as those of the embodiments described with reference to FIGS. 1A to 15, and their repetitive descriptions will be omitted. The substrate cleaning apparatus 1 of this embodiment functions as a pen-type substrate cleaning apparatus configured to clean an upper surface of a wafer W.

As shown in FIG. 16, the substrate cleaning apparatus 1 of this embodiment includes substrate holder 10 configured to hold and rotate a wafer W, a support post 92 that extends in the vertical direction, a swing arm 94 extending horizontally and having an end coupled to a distal end of the support post 92, a cleaning-member moving mechanism 93 coupled to the support post 92, a columnar pencil cleaning member 96 (e.g., a columnar sponge) rotatably attached to a lower surface of the other end of the swing arm 94, two upper liquid supply nozzles 14 and 15 for supplying liquid, as a cleaning liquid, to the upper surface of the wafer W, two lower liquid supply nozzles 16 and 17, periphery cleaning unit 20, and operation controller 9.

The substrate cleaning apparatus 1 of this embodiment can perform both cleaning of the upper surface of the wafer W by the pencil cleaning member 96 and cleaning of the periphery of the wafer W by the periphery cleaning unit 20. The pencil cleaning member 96 is coupled to a cleaning-member rotating mechanism (not shown) located within the swing arm 94 such that the pencil cleaning member 96 is rotated about its vertically extending central axis. The swing arm 94 is arranged above the wafer W.

The substrate holder 10 includes a plurality of horizontally movable spindles 90 (four spindles in FIG. 16) for holding the periphery of the wafer W with its surface facing up and rotating the wafer W horizontally. The plurality of spindles 90 are provided with a plurality of spin chucks 90a configured to hold the periphery of the wafer W. The spin chucks 90a are configured to rotate in the same direction at the same speed. When the spin chucks 90a rotate while holding the wafer W horizontally, the wafer W is rotated about its axis Cr in a direction indicated by arrow. The periphery cleaning unit 20 is arranged such that the pressing structure 22 is located between two of the four spindles 90.

When the cleaning-member moving mechanism 93 rotates the support post 92 by a predetermined angle, the swing arm 94 pivots within a plane parallel to the wafer W. This pivoting motion of the swing arm 94 causes the pencil cleaning member 96 to move over the wafer W in an arc-shaped path. Since a distal end of the swing arm 94 extends to the center O of the wafer W, the path of movement of the pencil cleaning member 96 passes through the center O of the wafer W. Furthermore, the pencil cleaning member 96 is moved to the periphery of the wafer W. Therefore, the path of movement of the pencil cleaning member 96 due to the rotation of the swing arm 94 has an arc shape whose radius is equal to the length of the swing arm 94. A range of movement of the pencil cleaning member 96 is from the periphery of the wafer W to a point beyond the center O of the wafer W.

The cleaning-member moving mechanism 93 is further configured to move the support post 92 vertically, so that the pencil cleaning member 96 can be pressed against the surface of the wafer W with a predetermined pressure. The pencil cleaning member 96 may be made of polyurethane foam, or PVA, for example. The operation controller 9 is electrically coupled to the cleaning-member moving mechanism 93 and the cleaning-member rotating mechanism (not shown). Operations of the cleaning-member moving mechanism 93 and the cleaning-member rotating mechanism are controlled by the operation controller 9.

The upper surface of wafer W is cleaned as follows. First, the substrate holder 10 horizontally holds the wafer W with its surface facing up, and rotates the wafer W about its axis Cr. With the wafer W rotated horizontally, the rinsing liquid is supplied to the surface of the wafer W from the liquid supply nozzle 14, and the chemical liquid is supplied to the surface of the wafer W from the liquid supply nozzle 15. While the pencil cleaning member 96 is rotated about its central axis, the swing arm 94 pivots to cause the pencil cleaning member 96 to move and come into contact with the surface of the wafer W which is rotating. As a result, the surface of the wafer W is scrubbed by the pencil cleaning member 96 in the presence of the cleaning liquid (i.e., the rinsing liquid and the chemical liquid).

In one embodiment, the process of cleaning the surface of the wafer W according to the embodiment described with reference to FIG. 16 is performed after the surface of the wafer is polished by CMP or the like. The process of cleaning the surface of the wafer W according to the embodiment described with reference to FIG. 16 and the process of cleaning the periphery of the wafer W described above may be performed simultaneously or separately In this embodiment, the substrate cleaning apparatus 1 includes the periphery cleaning unit 20 according to the embodiments described with reference to FIGS. 1A to 7C, while the substrate cleaning apparatus 1 may include the periphery cleaning unit 20 according to the embodiments described with reference to FIGS. 8 to 15.

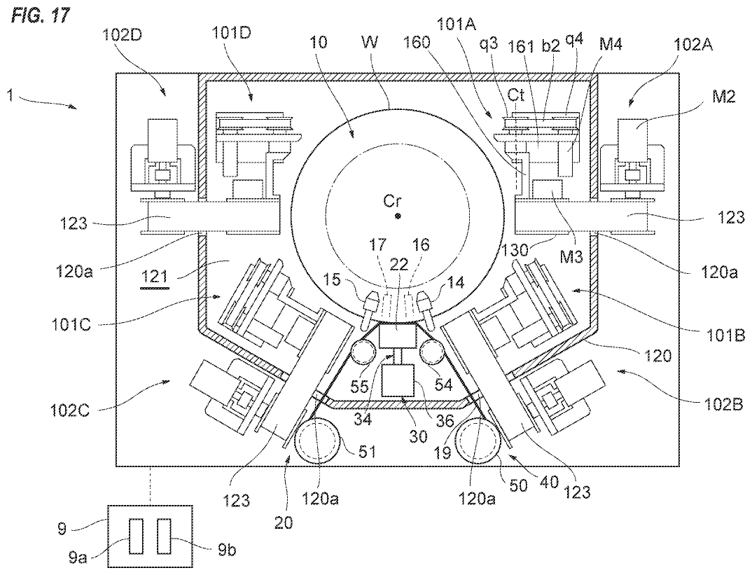

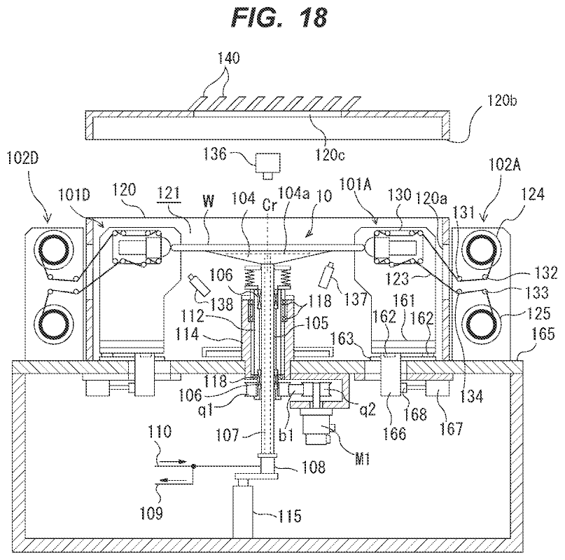

FIG. 17 is a plan view schematically showing still another embodiment of the substrate cleaning apparatus 1, and FIG. 18 is a vertical cross-sectional view of the substrate cleaning apparatus 1 shown in FIG. 17. Details of this embodiment, which will not be specifically described, are the same as those of the embodiments described with reference to FIGS. 1A to 15, and their repetitive descriptions will be omitted. The substrate cleaning apparatus 1 of this embodiment functions as a bevel polishing apparatus for polishing the periphery of the wafer W. The substrate cleaning apparatus 1 of the present embodiment can perform both polishing of the periphery of the wafer W and cleaning of the periphery of the wafer W by the periphery cleaning unit 20

As shown in FIGS. 17 and 18, the substrate cleaning apparatus 1 of this embodiment includes substrate holder 10 arranged in the center of the substrate cleaning apparatus 1, periphery cleaning unit 20, four polishing head assemblies 101A, 101B, 101C, and 101D arranged around the wafer W held by the substrate holder 10, tape supply-collection mechanisms 102A, 102B, 102C, and 102D arranged radially outwardly of the polishing head assemblies 101A, 101B, 101C, and 101D, two upper liquid supply nozzles 14 and 15 for supplying liquid, as a cleaning liquid, to the upper surface of the wafer W, two lower liquid supply nozzles 16 and 17, and operation controller 9.

The substrate holder 10 of this embodiment includes a dish-shaped holding stage 104 configure to hold the back surface of the wafer W by vacuum suction, a hollow shaft 105 that is coupled to the central portion of the holding stage 104, and a motor M1 configured to rotate the hollow shaft 105. The wafer W is placed on the holding stage 104 by a transfer mechanism (not shown) such that the center O (shown in FIG. 16) of the wafer W coincides with a central axis of the hollow shaft 105. The wafer W is horizontally held by the substrate holder 10.

The hollow shaft 105 is vertically movably supported by a plurality of ball spline bearings (linear motion bearings) 106. A groove 104a is formed in the upper surface of the holding stage 104. This groove 104a is coupled to a communication line 107 extending through the hollow shaft 105. The communication line 107 is coupled to a vacuum line 109 via a rotary joint 108 attached to the lower end of hollow shaft 105. The communication line 107 is further coupled to a nitrogen-gas supply line 110 for removing the processed wafer W from the holding stage 104. By switching between the vacuum line 109 and the nitrogen gas supply line 110, the wafer W is attracted to the upper surface of the holding stage 104 via vacuum or released from the upper surface of the holding stage 104.

The hollow shaft 105 is rotated by the motor M1 via a pulley q1 coupled to the hollow shaft 105, a pulley q2 attached to a rotating shaft of the motor M1, and a belt b1 riding on these pulleys q1 and q2. The rotating shaft of motor M1 extends parallel to the hollow shaft 105. With such a configuration, the wafer W held on the upper surface of the holding stage 104 is rotated by the motor M1.

The ball spline bearings 106 are fixed to a casing 112. Therefore, in this embodiment, the hollow shaft 105 is configured to be able to move linearly up and down with respect to the casing 112, and the hollow shaft 105 and the casing 112 rotate together. The hollow shaft 105 is coupled to an air cylinder (which is an elevating mechanism) 115, which allows the hollow shaft 105 and the holding stage 104 to move up and down.

Radial bearings 118 are interposed between the casing 112 and a casing 114 arranged concentrically outside the casing 112. The casing 112 is rotatably supported by the bearings 118. With such a configuration, the substrate holder 10 can rotate the wafer W about the axis Cr and can move the wafer W up and down along the axis Cr.

A partition wall 120 is provided to isolate the polishing head assemblies 101A to 101D from the tape supply-collection mechanisms 102A to 102D. An internal space of the partition wall 120 constitutes a processing chamber 121. The polishing head assemblies 101A to 101D and the holding stage 104 are arranged in the processing chamber 121, while the tape supply-collection mechanisms 102A to 102D are arranged outside the processing chamber 121.

A top surface of the partition wall 120 has an opening 120c covered with a louver 140. The partition wall 120 has a plurality of openings 120a through which polishing tapes 123 (which will be described later) pass, respectively. The partition wall 120 further has a transporting port 120b for transporting the wafer W into and out of the processing chamber 121. During cleaning (or polishing), the transporting port 120b is closed by a shutter (not shown). Therefore, a fan mechanism (not shown) is used to exhaust air, thereby forming downflow of clean air inside the processing chamber 121.

Each of the polishing head assemblies 101A, 101B, 101C, and 101D functions as a substrate processing unit for polishing the bevel portion of the wafer W. The polishing head assemblies 101A, 101B, 101C and 101D have the same configurations, and the tape supply-collection mechanisms 102A, 102B, 102C and 102D have the same configurations. The polishing head assembly 101A and the tape supply-collection mechanism 102A will be described below.

The tape supply-collection mechanism 102A includes a feeding reel 124 for supplying the polishing tape 123, which is a polishing tool, to the polishing head assembly 101A, and a collecting reel 125 for collecting the polishing tape 123 that has been used for polishing of the wafer W. The feeding reel 124 is arranged above the collecting reel 125. Motors M2 are coupled to the feeding reel 124 and the collecting reel 125, respectively (only the motor M2 coupled to the feeding reel 124 is shown in Figures). Each motor M2 can apply a constant torque in a predetermined rotational direction to apply a predetermined tension to the polishing tape 123.

The polishing tape 123 is an elongated tape-shaped polishing tool, and one side of the polishing tape 123 constitutes a polishing surface. The polishing tape 123 is wound around the feeding reel 124, which is installed on the tape supply-collection mechanism 102A. One end of the polishing tape 123 is attached to the collecting reel 125, which collects the polishing tape 123 by winding the polishing tape 123 that has been supplied to the polishing head assembly 101A. The polishing head assembly 101A includes a polishing head 130 for bringing the polishing tape 123, supplied from the tape supply-collection mechanism 102A, into contact with the periphery of the wafer W. The polishing tape 123 is supplied to the polishing head 130 such that a polishing surface of the polishing tape 123 faces the wafer W.

The tape supply-collection mechanism 102A has a plurality of guide rollers 131, 132, 133, and 134. The polishing tape 123 is guided by these guide rollers 131 to 134. The polishing tape 123 is supplied from the feeding reel 124 to the polishing head 130 through the opening 120a, and the polishing tape 123 that has been used for polishing is collected by the collecting reel 125 through the opening 120a.

As shown in FIG. 18, an upper supply nozzle 136 is arranged over the upper surface of the wafer W to supply a polishing liquid onto the center of the upper surface of the wafer W held by the substrate holder 10. A lower supply nozzle 137 is provided for supplying a polishing liquid onto a boundary between the back surface of the wafer W and the holding stage 104 (specifically, a periphery of the bolding stage 104). Pure water is usually used as the polishing liquid, but ammonia can also be used when silica is used as abrasive grains of the polishing tape 123. The substrate cleaning apparatus 1 includes a cleaning nozzle 138 for cleaning the polishing head 130 after the polishing process. After the wafer W is elevated by the substrate holder 10 after the polishing process, cleaning water is sprayed toward the polishing head 130, so that the polishing head 130 can be cleaned with the cleaning water. The upper supply nozzle 136 and the lower supply nozzle 137 are coupled to a polishing-liquid supply source (not shown), and the cleaning nozzle 138 is coupled to a cleaning-water supply source (not shown)

As shown in FIG. 17, the polishing head 130 is fixed to one end of an arm 160. The arm 160 is rotatable around an axis Ct parallel to a tangential line of the wafer W. The other end of the arm 160 is coupled to a motor M4 via pulleys q3 and q4 and a belt b2. As the motor M4 rotates clockwise and counterclockwise by a predetermined angle, the arm 160 rotates by a predetermined angle about the axis Ct. In this embodiment, the motor M4, the arm 160, the pulleys q3 and q4, and the belt b2 constitute a tilting mechanism for tilting the polishing head.

As shown in FIG. 18, the tilting mechanism is mounted to a plate-shaped movable table 161. The movable table 161 is movably coupled to a base plate 165 via guide 162 and rail 163.

The rail 163 extends linearly along the radial direction of the wafer W held by the substrate holder 10, and the movable table 161 is linearly movable along the radial direction of the wafer W. A coupling plate 166 passing through the base plate 165 is attached to the movable table 161, and a linear actuator 167 is attached to the coupling plate 166 via a joint 168. The linear actuator 167 is fixed directly or indirectly to the base plate 165.

The linear actuator 167 may include an air cylinder or a combination of a positioning motor and a ball screw. The linear actuator 167, the rail 163, and the guide 162 constitute a moving mechanism for linearly moving the polishing head 130 along the radial direction of the wafer W. Specifically, the moving mechanism operates to bring the polishing head 130 closer to and away from the wafer W along the rail 163. On the other hand, the tape supply-collection mechanism 102A is fixed to the base plate 165.

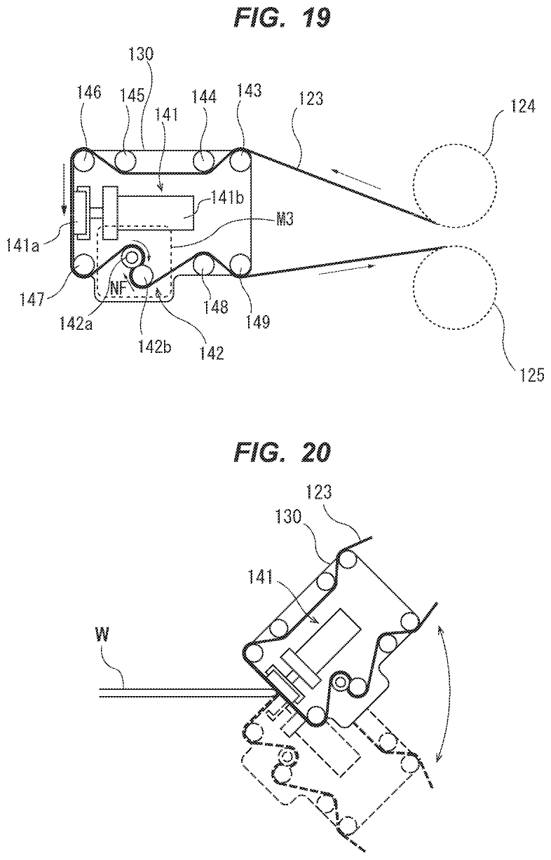

FIG. 19 is an enlarged view of the polishing head 130. As shown in FIG. 19, the polishing head 130 includes a pressing mechanism 141 configured to press the polishing surface of the polishing tape 123 against the wafer W with a predetermined force, and a tape advancing mechanism 142 configured to advance the polishing tape 123 from the feeding reel 124 to the collecting reel 125. The polishing head 130 has a plurality of guide rollers 143, 144, 145, 146, 147, 148, and 149. These guide rollers are arranged to guide the polishing tape 123 such that the polishing tape 123 moves in a direction perpendicular to the tangential direction of the wafer W.

The tape advancing mechanism 142 provided on the polishing head 130 includes a tape advancing roller 142a, a tape gripping roller 142b, and a motor M3 for rotating the tape advancing roller 142a. The motor M3 is provided on the side surface of the polishing head 130, and the tape advancing roller 142a is coupled to a rotating shaft of the motor M3. The polishing tape 123 is wound on the tape advancing roller 142a by about half the circumference of the tape advancing roller 142a. The tape gripping roller 142b is provided next to the tape advancing roller 142a. The tape gripping roller 142b is supported by a mechanism (not shown) which is configured to generate a force in a direction indicated by arrow NF in FIG. 19 (i.e., in a direction toward the tape advancing roller 142a) so that the tape gripping roller 142b presses the tape advancing roller 142a.

The polishing tape 123 is sandwiched between the tape advancing roller 142a and the tape gripping roller 142b. When the motor M3 rotates in the direction of the arrow shown in FIG. 19, the tape advancing roller 142a rotates to advance the polishing tape 123 from the feeding reel 124 to the collecting reel 125 via the polishing head 130. The tape gripping roller 142b is configured to be rotatable about its own axis and rotates as the polishing tape 123 is advanced.

The pressing mechanism 141 includes a pressing pad 141a that supports the back surface of the polishing tape 123, and an air cylinder (or an actuator) 141b configured to move the pressing pad 141a toward the periphery of the wafer W. The polishing head 130 presses the polishing tape 123 from its back side with the pressing mechanism 141 to polish the periphery of the substrate W by bringing the polishing surface of the polishing tape 123 into contact with the periphery of the substrate W. The pressing force on the wafer W is regulated by the air pressure supplied to the air cylinder 141b.

The tilting mechanisms, the pressing mechanisms 141, and the tape advancing mechanisms 142 for the four polishing head assemblies 101A to 101D, the moving mechanisms for moving these polishing head assemblies, the four tape supply-collection mechanisms 102A to 102D, the upper supply nozzle 136, the lower supply nozzle 137, the cleaning nozzle 138, and the air cylinder 115 are electrically coupled to the operation controller 9. The operations of the tilting mechanisms, the pressing mechanisms 141, and the tape advancing mechanisms 142 for the four polishing head assemblies 101A to 101D, the moving mechanisms for moving these polishing head assemblies, the four tape supply-collection mechanisms 102A to 102D, the upper supply nozzle 136, the lower supply nozzle 137, the cleaning nozzle 138, and the air cylinder 115 are controlled by the operation controller 9.

The tilting mechanisms, the pressing mechanisms 141, and the tape advancing mechanisms 142 for the four polishing head assemblies 101A to 101D, the moving mechanisms for moving these polishing head assemblies are configured to be operable independently. Although four sets of polishing head assemblies and tape supply-collection mechanisms are provided in this embodiment, the number of polishing head assemblies and tape supply-collection mechanisms is not limited to this embodiment.

FIG. 20 shows the polishing head 130 when polishing the bevel portion of the wafer W. The periphery of the wafer W is polished as follows. First, the wafer W is held and rotated by the substrate holder 10. Specifically, the wafer W is transported to a predetermined position above the holding stage 104, and the holding stage 104 is then raised. The wafer W is held via suction on the upper surface of the holding stage 104. The holding stage 104 holding the wafer W is then lowered to a predetermined polishing position, and the substrate holder 10 rotates the wafer W together with the holding stage 104. Further, the polishing liquid is supplied onto the surface of the wafer W from the upper supply nozzle 136. The polishing liquid may be supplied to the periphery of the wafer W from the lower supply nozzle 137.

In this state, as shown in FIG. 20, the pressing mechanism 141 presses the polishing tape 123 against the periphery (for example, the bevel portion) of the wafer W while the tilt angle of the polishing bead 130 is continuously changed by the tilting mechanism. During polishing of the wafer W, the polishing tape 123 is advanced at a predetermined speed by the tape advancing mechanism 142. After the polishing process, the air cylinder 115 elevates the wafer W together with the holding stage 104 and the hollow shaft 105 to the transfer position. The wafer W is then removed from the holding stage 104 at this transfer position.

In this embodiment, both the polishing of the periphery of the wafer W and the cleaning of the periphery of the wafer W can be performed without transporting the wafer W. As a result, the wafer W can be processed efficiently. The cleaning process of the periphery of the wafer W and the polishing process of the periphery of the wafer W may be performed simultaneously or separately. The cleaning process of the periphery of the wafer W may be performed at the same time as the polishing process of the wafer W or may be performed immediately after the polishing process of the wafer W, so that the cleaning effect of the periphery of the wafer W can be further improved.

The periphery cleaning unit 20 is arranged such that the pressing structure 22 is located between two of the four polishing head assemblies 101A to 101D. In this embodiment, the periphery cleaning unit 20 is arranged between the polishing head assembly 101B and the polishing head assembly 101C, but the arrangement of the periphery cleaning unit 20 is not limited to this embodiment.

The cleaning tape 19 is supplied to the pressing structure 22 through the opening 120a. In this embodiment, the pressing structure 22, the pressing-structure moving mechanism 30, the first guide roller 54, and the second guide roller 55 are arranged inside the processing chamber 121, and the tape advancing unit 40 is arranged outside the processing chamber 121.

In this embodiment, the substrate cleaning apparatus 1 includes the periphery cleaning unit 20 according to the embodiments described with reference to FIGS. 1A to 7C, but the substrate cleaning apparatus 1 may include the periphery cleaning unit 20 according to the embodiments described with reference to FIGS. 8 to 15. In this case, a new opening 120a for passing the base plate 62 therethrough may be provided in the partition wall 120, or the existing opening 120a may be widened for passing the base plate 62 therethrough. The entire periphery cleaning unit 20 may be arranged in the processing chamber 121.

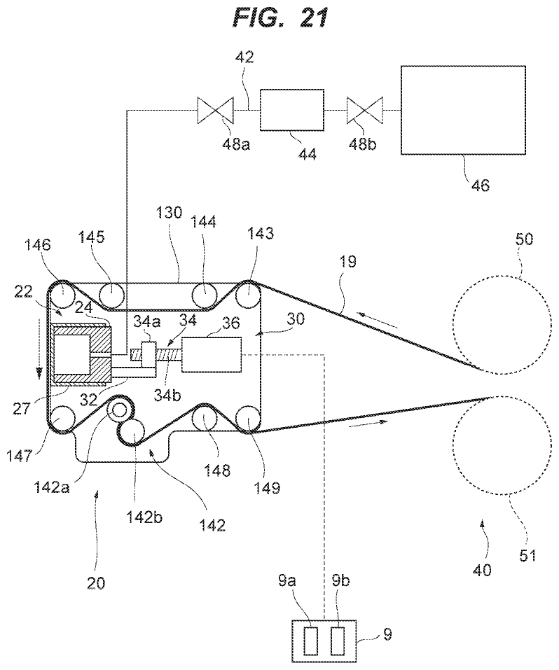

In one embodiment, the polishing head 130 of at least one of the polishing head assemblies 101A to 101D may include the pressing structure 22 and the pressing-structure moving mechanism 30 coupled to the pressing structure 22. In this case, as shown in FIG. 21, the pressing structure 22 and the pressing-structure moving mechanism 30 are provided in the polishing head 130 instead of the pressing mechanism 141. The reels 50, 51 and the reel rotating motors 52, 53 (not shown in FIG. 21) are provided in at least one of the tape supply-collection mechanisms 102A to 102D in place of the feeding reel 124, the collecting reel 125, and the motor M2. With these configurations, the periphery cleaning unit 20 is configured by the polishing head assembly and the tape supply-collection mechanism.

In this embodiment, the cleaning tape 19 extends from the first reel 50 to the second reel 51 via the polishing head 130. The cleaning tape 19 is guided by the guide rollers 143 to 149. Details of this embodiment, which will not be specifically described, are the same as the embodiments described with reference to FIGS. 1A to 7C. In this embodiment, the tape advancing unit 40 is configured by the tape advancing mechanism 142, the reels 50 and 51, and the reel rotating motors 52 and 53.

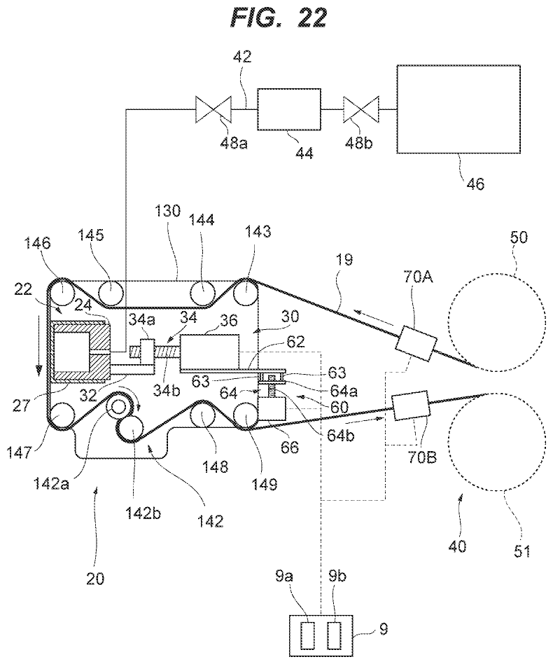

In one embodiment, as shown in FIG. 22, the pressing-structure moving mechanism 30 provided in the polishing head 130 may be coupled to the vertically-moving mechanism 60, and the periphery cleaning unit 20 may include the tape cleaning mechanism 70A, 70B. In this embodiment, the vertically-moving mechanism 60 is coupled to the pressing-structure moving mechanism 30 via base plate 62. The vertically-moving mechanism 60 is configured to vertically move the pressing structure 22 and the pressing-structure moving mechanism 30 together. In this embodiment, the tape cleaning mechanism 70A is arranged between the polishing head 130 and the first reel 50, and the tape cleaning mechanism 70B is arranged between the polishing head 130 and the second reel 51. The embodiment described with reference to FIG. 15 can be applied to the embodiments described with reference to FIGS. 21 and 22.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### Industrial Applicability

The present invention is applicable to a substrate cleaning apparatus and a substrate cleaning method for cleaning the periphery of a substrate, such as a semiconductor wafer.

### Reference Signs List

1 substrate cleaning apparatus

9 operation controller

10 substrate holder

11 spindle

11a spin roller

12 upper roll cleaning member

13 lower roll cleaning member

14 upper liquid supply nozzle

15 upper liquid supply nozzle

16 lower liquid supply nozzle

17 lower liquid supply nozzle

19 cleaning tape

20 periphery cleaning unit

22 pressing structure

24 support member

24a opening

25 base

26a, 26b, 26c, 26d protrusion

27 elastic element

30 pressing-structure moving mechanism

34 ball-screw mechanism

36 motor

40 tape advancing unit

42 fluid delivery line

44 pressure regulator

46 fluid supply source

50 first reel

52 first reel rotating motor

51 second reel

53 second reel rotating motor

54 first guide roller

55 second guide roller

60 vertically-moving mechanism

62 base plate

63 fixing member

64 ball-screw mechanism

66 motor

70A tape cleaning mechanism

70B tape cleaning mechanism

74 tape support member

76 cleaning-liquid supply nozzle

78 casing

80 cleaning brush

82 sensor

90 spindle

92 support post

93 cleaning-member moving mechanism

94 swing arm

96 pencil cleaning member

101A, 101B, 101C, 101D polishing head assembly

102A, 102B, 102C, 102D tape supply-collection mechanism

104 holding stage

105 hollow shaft

112 casing

114 casing

115 air cylinder

120 partition wall

121 processing chamber

123 polishing tape

124 feeding reel

125 collecting reel

130 polishing head

136 upper supply nozzle

137 lower supply nozzle

141 pressing mechanism

142 tape advancing mechanism

161 movable table

162 guide

163 rail

167 linear actuator

1. A substrate cleaning apparatus comprising:
a substrate holder configured to hold and rotate a substrate;
a pressing structure having an internal space and configured to press a cleaning tape against a periphery of the substrate;
a pressing-structure moving mechanism configured to control a position of the pressing structure in a radial direction of the substrate; and
a pressure regulator configured to regulate pressure in the internal space,
wherein the pressing structure includes:
a hollow support member having an opening; and
an elastic element configured to support the cleaning tape, the elastic element being arranged to close the opening.

2. The substrate cleaning apparatus according to claim 1, wherein the pressing-structure moving mechanism includes a ball screw mechanism coupled to the pressing structure, and a motor configured to actuate the ball screw mechanism.

3. The substrate cleaning apparatus according to claim 2, wherein the motor is a servomotor.

4. The substrate cleaning apparatus according to claim 1, wherein the pressure regulator is an electropneumatic regulator.

5. The substrate cleaning apparatus according to claim 1, further comprising a vertically-moving mechanism configured to vertically move the pressing structure.

6. The substrate cleaning apparatus according to claim 1, further comprising a tape cleaning mechanism configured to clean the cleaning tape, the tape cleaning mechanism including a cleaning-liquid supply nozzle configured to supply cleaning liquid to a surface of the cleaning tape.

7. The substrate cleaning apparatus according to claim 6, wherein the tape cleaning mechanism further includes a cleaning brush configured to contact the surface of the cleaning tape to clean the cleaning tape.

8. The substrate cleaning apparatus according to claim 1, further comprising a first reel and a second reel holding both ends of the cleaning tape, respectively, the first reel and the second reel being arranged such that the cleaning tape advances in a horizontal direction.

9. A substrate cleaning method comprising:
holding and rotating a substrate by a substrate holder;
while advancing a cleaning tape in a certain direction, pressing the cleaning tape against a periphery of the substrate by a pressing structure having an internal space, thereby cleaning the periphery of the substrate,
wherein cleaning the periphery of the substrate comprises controlling a position of the pressing structure in a radial direction of the substrate by a pressing-structure moving mechanism, and regulating pressure in the internal space of the pressing structure by a pressure regulator,
the pressing structure includes:
a hollow support member having an opening; and
an elastic element supporting the cleaning tape, the elastic element being arranged to close the opening.

10. The substrate cleaning method according to claim 9, wherein the pressing-structure moving mechanism includes a ball screw mechanism coupled to the pressing structure, and a motor configured to actuate the ball screw mechanism.

11. The substrate cleaning method according to claim 10, wherein the motor is a servomotor.

12. The substrate cleaning method according to claim 9, wherein the pressure regulator is an electropneumatic regulator.

13. The substrate cleaning method according to claim 9, wherein cleaning the periphery of the substrate further comprises moving the pressing structure up and down while cleaning the periphery of the substrate.

14. The substrate cleaning method according to claim 9, further comprising supplying a cleaning liquid by a tape cleaning mechanism to the cleaning tape that has contacted the periphery of the substrate during cleaning of the periphery of the substrate to thereby clean the cleaning tape.

15. The substrate cleaning method according to claim 9, further comprising supplying a cleaning liquid by a tape cleaning mechanism to the cleaning tape that has contacted peripheries of a predetermined number of substrates while advancing the cleaning tape in a certain direction to thereby clean the cleaning tape.

16. The substrate cleaning method according to claim 14, further comprising cleaning the periphery of the substrate while advancing the cleaning tape in an opposite direction after the cleaning tape is completely wound on either a first reel or a second reel, the first reel holding one end of the cleaning tape, and the second reel holding other end of the cleaning tape.

17. The substrate cleaning method according to claim 9, wherein advancing the cleaning tape in the certain direction comprises advancing the cleaning tape in a horizontal direction.
